(19) United States
(12) Patent Application Publication
(10) Pub. No.: US 2026/0182072 A1
(43) Pub. Date: Jun. 25, 2026

(54) ELECTRONIC COMPONENT

(71) Applicant: CANON KABUSHIKI KAISHA, Tokyo (JP)

(72) Inventor: YU KATASE, Kanagawa (JP)

(21) Appl. No.: 19/423,722

(22) Filed: Dec. 17, 2025

(30) Foreign Application Priority Data
Dec. 25, 2024 (JP) 2024-228895

(51) Int. Cl. H10F 39/00; G01S 7/481

(52) U.S. Cl. CPC H10F 39/811; G01S 7/4816; H10F 39/804; H10F 39/809

(57) ABSTRACT

An electronic component includes: a first semiconductor substrate arranged on a substrate, having a first region and a second region outside the first region; a second semiconductor substrate bonded to the first semiconductor substrate; an optical member facing the first and second semiconductor substrates; first electrodes arranged in the second region; second electrodes arranged in a region of the substrate outside the first semiconductor substrate; and a conductive wire connecting the first and second electrodes. The second semiconductor substrate is arranged between the first region and the first electrode. A maximum height of the conductive wire is h1, a height of the second semiconductor substrate is h2, and h1 < h2 is satisfied. The conductive wire has a region inclined at an angle θ formed between the conductive wire and a normal line of the surface on which the first electrode is arranged. The angle θ is less than 45°.

### BACKGROUND

### Field of the Technology

The present disclosure relates to an electronic component.

### Description of the Related Art

Japanese Patent Laid-Open No. 2014-116358 discloses a semiconductor device in which a second semiconductor chip is arranged on a first chip on which a photoelectric conversion portion is formed and a flare preventive plate for shielding light is provided on the second semiconductor chip.

In an electronic component including an image sensor, a semiconductor substrate including the image sensor and a substrate are electrically connected by wire bonding. In such a configuration, it is difficult with the technology described in Japanese Patent Laid-Open No. 2014-116358 to suppress a wire ghost phenomenon in which light incident from outside and hitting a wire is reflected and enters the image sensor, appearing in an image captured by the image sensor.

### SUMMARY

The present disclosure is directed to an electronic component capable of suppressing the influence of a wire ghost phenomenon.

According to one aspect of the present disclosure, there is provided an electronic component including: a substrate; a first semiconductor substrate arranged on the substrate, the first semiconductor substrate having a first region that detects light and a second region outside the first region; a second semiconductor substrate arranged on the first semiconductor substrate and bonded to the first semiconductor substrate; an optical member facing the first semiconductor substrate and the second semiconductor substrate with a hollow portion therebetween, the optical member being transparent to the light; a plurality of first electrodes arranged in the second region; a plurality of second electrodes arranged in a region of the substrate that is outside a region where the first semiconductor substrate is arranged; and a conductive wire connecting the first electrode and the second electrode, wherein the second semiconductor substrate is arranged between the first region and the first electrode, wherein, when a maximum height of the conductive wire from a surface of the first semiconductor substrate on which the first electrode is arranged is defined as h1, and a height of the second semiconductor substrate is defined as h2, h1 < h2 is satisfied, wherein the conductive wire has a region that is inclined outward with respect to the first semiconductor substrate at an angle θ, the angle θ being formed between the conductive wire and a normal line of the surface on which the first electrode is arranged, in a region of the conductive wire up to the height h1, and wherein the angle θ is less than 45°.

According to another aspect of the present disclosure, there is provided an electronic component including: a substrate; a first semiconductor substrate arranged on the substrate, the first semiconductor substrate having a first region that detects light and a second region outside the first region; a second semiconductor substrate arranged on the first semiconductor substrate and bonded to the first semiconductor substrate; an optical member that is transparent to the light; a plurality of first electrodes arranged in the second region; a plurality of second electrodes arranged in a region of the substrate that is outside a region where the first semiconductor substrate is arranged; and a conductive wire connecting the first electrode and the second electrode, wherein the second semiconductor substrate is arranged between the first region and the first electrode, and wherein the optical member is bonded to the second semiconductor substrate by a second bonding member so as to cover at least the first region.

Features of the present disclosure will become apparent from the following description of embodiments with reference to the attached drawings. The following description of embodiments is described by way of example.

### BRIEF DESCRIPTION OF THE DRAWINGS

FIG. 1 is a cross-sectional view illustrating an electronic component according to a first embodiment.

FIG. 2 is a plan view illustrating an electronic component according to the first embodiment.

FIG. 3A is a cross-sectional view for explaining a wire ghost phenomenon.

FIG. 3B is a cross-sectional view for explaining the wire ghost phenomenon.

FIG. 4A is a cross-sectional view illustrating the electronic component according to the first embodiment.

FIG. 4B is a cross-sectional view illustrating the electronic component according to the first embodiment.

FIG. 5A is a cross-sectional view for explaining the electronic component according to the first embodiment and a wire ghost phenomenon.

FIG. 5B is a sectional view for explaining the electronic component according to the first embodiment and the wire ghost phenomenon.

FIG. 5C is a sectional view for explaining the electronic component according to the first embodiment and the wire ghost phenomenon.

FIG. 5D is a sectional view for explaining the electronic component according to the first embodiment and the wire ghost phenomenon.

FIG. 5E is a sectional view for explaining the electronic component according to the first embodiment and the wire ghost phenomenon.

FIG. 6A is a sectional view for explaining the electronic component according to the first embodiment and the wire ghost phenomenon.

FIG. 6B is a sectional view for explaining the electronic component according to the first embodiment and the wire ghost phenomenon.

FIG. 7 is a plan view illustrating the electronic component according to the first embodiment.

FIG. 8 is a plan view illustrating the electronic component according to the first embodiment.

FIG. 9 is a plan view illustrating the electronic component according to the first embodiment.

FIG. 10 is a plan view illustrating an electronic component according to a second embodiment.

FIG. 11 is a cross-sectional view illustrating the electronic component according to the second embodiment.

FIG. 12A is an enlarged view of a cross-sectional view illustrating the electronic component according to the second embodiment.

FIG. 12B is an enlarged view of a cross-sectional view illustrating the electronic component according to the second embodiment.

FIG. 13 is a cross-sectional view illustrating an electronic component according to a third embodiment.

FIG. 14 is a plan view illustrating the electronic component according to the third embodiment.

FIG. 15A is a cross-sectional view for explaining the electronic component according to the third embodiment and a wire ghost phenomenon.

FIG. 15B is a cross-sectional view for explaining the electronic component according to the third embodiment and the wire ghost phenomenon.

FIG. 16A is a cross-sectional view illustrating the electronic component according to the third embodiment.

FIG. 16B is a cross-sectional view illustrating the electronic component according to the third embodiment.

FIG. 17 is a plan view illustrating the electronic component according to the third embodiment.

FIG. 18 is a plan view illustrating the electronic component according to the third embodiment.

FIG. 19 is a plan view illustrating the electronic component according to the third embodiment.

FIG. 20 is a cross-sectional view illustrating the electronic component according to the third embodiment.

FIG. 21A is an enlarged cross-sectional view illustrating the electronic component according to the third embodiment.

FIG. 21B is an enlarged cross-sectional view illustrating the electronic component according to the third embodiment.

FIG. 22 is a cross-sectional view illustrating the electronic component according to the third embodiment.

FIG. 23 is a block diagram illustrating a schematic configuration of a photoelectric conversion system according to a fourth embodiment.

FIG. 24A is a diagram illustrating an example of a configuration of a photoelectric conversion system and a movable object according to a fifth embodiment.

FIG. 24B is a diagram illustrating an example of a configuration of the photoelectric conversion system and the movable object according to the fifth embodiment.

### DESCRIPTION OF THE EMBODIMENTS

The following embodiments are for the purpose of embodying the technical concept of the present disclosure and are not intended to limit the present disclosure. The sizes and positional relationships of the members illustrated in the respective drawings may be exaggerated for the sake of clarity. In the following description, the same components may be denoted by the same reference numerals, and their explanations may be omitted.

In the following description, embodiments of the present disclosure will be described in detail with reference to the drawings. Note that, in the following description, terms indicating specific directions or positions (such as “up”, “down”, “right”, “left”, and other words containing these terms, for example) will be used as necessary. The use of the terms is intended to facilitate understanding of the embodiments with reference to the drawings, and the technical scope of the present disclosure is not limited by the meaning of the terms.

In the specification, a plan view means a view from a direction perpendicular to a light incident surface of a substrate such as a semiconductor substrate or the like. A cross-sectional view means a view from a direction perpendicular to a surface parallel to a direction perpendicular to the light incident surface of the substrate. Note that, when the light incident surface of the substrate is rough when viewed microscopically, the plan view and the cross-sectional view are defined based on the light incident surface of the substrate when viewed macroscopically.

### First Embodiment

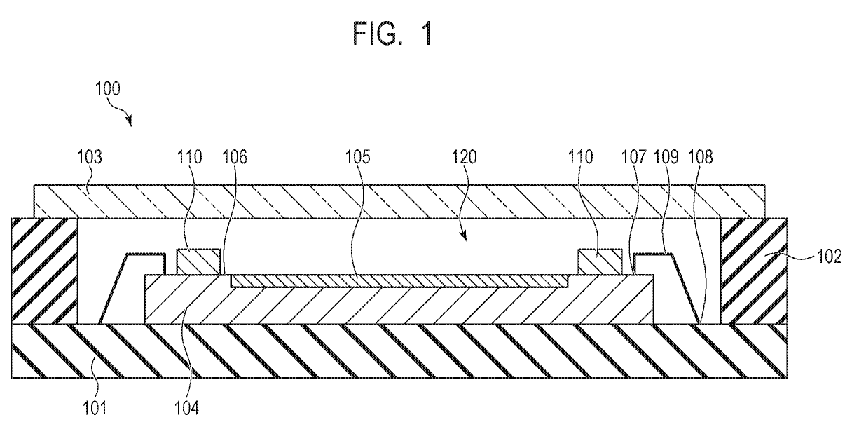

An electronic component according to a first embodiment of the present disclosure is described with reference to FIG. 1 to FIG. 9.

In an electronic component mounted with a semiconductor substrate having a detection region to detect light, there may occur a phenomenon called a wire ghost phenomenon in which light incident from outside hits a conductive wire, and the light is reflected and enters the detection region, appearing an image captured by the detection region. Generally, since the conductive wire is made of metal such as gold, silver, aluminum, copper, an alloy thereof, or the like, the wire is highly reflective of light. The electronic component according to the present embodiment is capable of suppressing such a wire ghost phenomenon.

FIG. 1 is a sectional view illustrating an electronic component 100 according to the present embodiment. As illustrated in FIG. 1, the electronic component 100 according to the present embodiment includes a substrate 101, a frame body 102, an optical member 103, a first semiconductor substrate 104, and second semiconductor substrates 110.

The frame body 102 is bonded to the substrate 101. The substrate 101 is arranged so as to cover an opening on one side of the frame body 102. The optical member 103 is bonded to the frame body 102 so as to cover an opening on the other side. The outer shape of the electronic component 100 is formed by the substrate 101, the frame body 102 and the optical member 103, which are thus bonded. A hollow portion 120 surrounded by the frame body 102 and the optical member 103 is formed in the electronic component 100.

The first semiconductor substrate 104 is arranged and bonded on the substrate 101 in the hollow portion 120. The first semiconductor substrate 104 is electrically connected to the substrate 101 via conductive wires 109 by wire bonding.

The second semiconductor substrates 110 are arranged on the first semiconductor substrate 104 in the hollow portion 120 and bonded to the first semiconductor substrate 104. The second semiconductor substrates 110 are electrically connected to the first semiconductor substrate 104 by conductive members (not illustrated). The first semiconductor substrate 104 is electrically connected to the second semiconductor substrates 110 by, for example, solder ball bonding, bump bonding, hybrid bonding without using bumps, or the like.

The substrate 101 is formed of, for example, a ceramic such as alumina, aluminum nitride, or the like as a main material. Further, the substrate 101 may be formed of, for example, a glass epoxy as a main material. The substrate 101 formed of a ceramic is advantageous for heat dissipation due to its high thermal conductivity. The substrate 101 formed of a glass epoxy is advantageous for reducing weight. A circuit (not illustrated) connected to the first semiconductor substrate 104 via the conductive wires 109 is formed on or in the substrate 101.

The frame body 102 is formed of, for example, a ceramic such as alumina, aluminum nitride or the like, a glass epoxy, a resin material, a metal material, or the like similarly to the substrate 101. When the frame body 102 is formed of a ceramic and the substrate 101 is also formed of the ceramic, the substrate 101 and the frame body 102 may also be formed as one integrally constituted material having a recessed shape. When the frame body 102 is formed of a material different from the substrate 101, from the viewpoint of bonding reliability, it is preferable to select appropriate materials for the materials of the substrate 101 and the frame body 102, such as those having near coefficients of linear thermal expansion or the like, for example.

The optical member 103 has translucency and transmits light which is to be detected by a detection region of the first semiconductor substrate 104. The optical member 103 is formed of, for example, glass, crystal, sapphire, or the like. The optical member 103 formed of crystal or sapphire may also function as a low-pass filter (LPF). Since sapphire has higher strength than crystal, the optical member 103 formed of sapphire may be made thinner. That is, the optical member 103 formed of sapphire is advantageous for miniaturization of the entire electronic component 100. Further, the coefficient of linear thermal expansion of sapphire is almost the same as that of alumina. Therefore, when the frame body 102 is formed of alumina, the optical member 103 formed of sapphire can improve bonding reliability between the frame body 102 and the optical member 103. An anti-reflection coating or an infrared cut coating may be applied to the optical member 103. In the present embodiment, from the viewpoint of suppressing reflection of light, it is preferable that the anti-reflection coating is applied to at least one surface or both surfaces of the surface of the optical member 103 facing the first semiconductor substrate 104 and the second semiconductor substrate 110, and the surface opposite thereto.

The first semiconductor substrate 104 is, for example, a silicon substrate, and has a detection region for detecting light, which is provided in a central region 105 on the side of the optical member 103. A plurality of image sensors, for example, may be formed in the detection region. The image sensors may be, for example, CMOS (Complementary Metal-Oxide Semiconductor) image sensors or may be avalanche diodes. When the image sensor is avalanche diodes, the avalanche diode may be an SPAD (Single Photon Avalanche Diode).

The second semiconductor substrate 110 is, for example, a silicon substrate and may include a circuit such as, for example, a memory circuit or the like. By conducting the second semiconductor substrate 110 with the first semiconductor substrate 104 over a short distance, high-speed transmission of signals between them becomes possible.

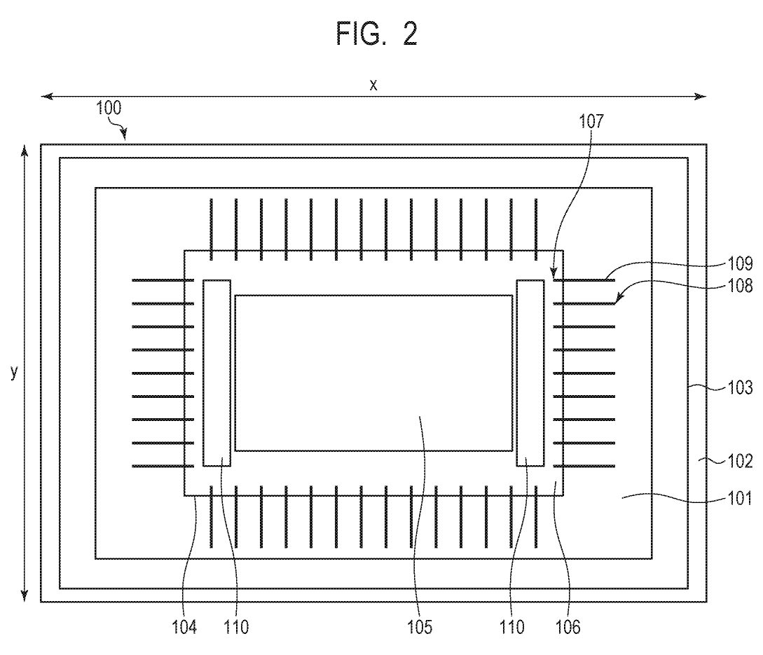

FIG. 2 is a plan view illustrating the electronic component 100 according to the present embodiment when viewed from the side of the optical member 103. As illustrated in FIG. 2, the substrate 101, the frame body 102, the optical member 103, and the first semiconductor substrate 104 each have a rectangular outer shape and are arranged so that their longitudinal and lateral directions are aligned. Here, assuming that the length of the electronic component 100 in the longitudinal direction is x and the length of the electronic component in the lateral direction is y, both of x and y are in the range of about 10 mm to 60 mm, but the size of the electronic component 100 is not limited to this range.

The first semiconductor substrate 104 having a rectangular shape has a rectangular central region 105 as a first region and a peripheral region 106 as a second region arranged around the central region 105. The central region 105 is arranged in the center of the electronic component 100. The peripheral region 106 is provided with a plurality of first electrodes 107. A plurality of second electrodes 108 are provided in a region of the substrate 101 outside the region where the first semiconductor substrate 104 is arranged so as to correspond to the plurality of first electrodes 107. The plurality of first electrodes 107 and the plurality of second electrodes 108 are connected by the plurality of conductive wires 109.

The second semiconductor substrates 110 are arranged on the peripheral region 106 of the first semiconductor substrate 104. More specifically, each of the second semiconductor substrates 110 is arranged between the central region 105 and the first electrode 107.

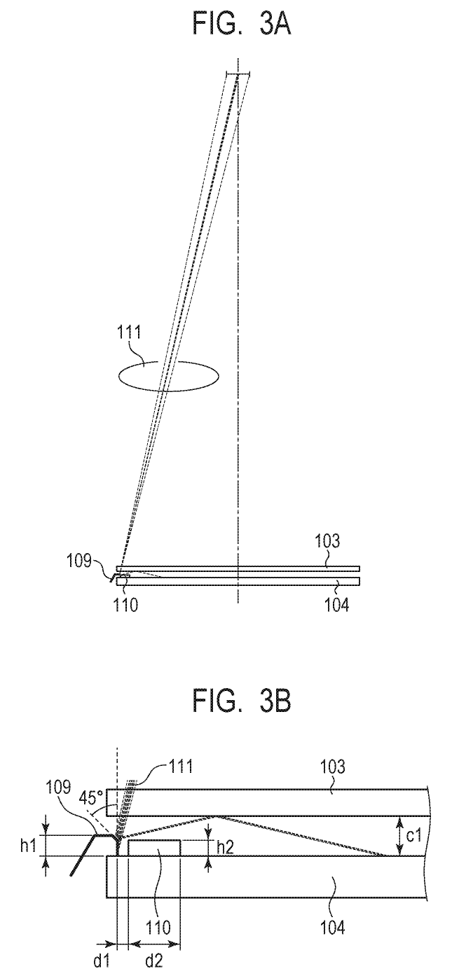

FIG. 3A and FIG. 3B are sectional views for explaining the wire ghost phenomenon. Note that, for convenience, FIG. 3A and FIG. 3B illustrate an electronic component in which the wire ghost phenomenon can occur using reference numerals similar to those of the electronic components 100 according to the present embodiment. FIG. 3A illustrates a state in which incident light 111 incident on the electronic component from above the optical member 103 hits the conductive wire 109 and is reflected. Strictly speaking, the path of incident light 111 passing through the optical member 103 slightly changes according to the refractive index of the optical member 103, but for the sake of simplification, the incident light 111 is illustrated as linear incident light. FIG. 3B is an enlarged cross-sectional view illustrating the vicinity of the conductive wire 109 in FIG. 3A.

In the electronic component illustrated in FIG. 3A and FIG. 3B, when the height of the conductive wire 109 from the surface on which the first electrode 107 is arranged is h1 and the height of the second semiconductor substrate 110 is h2, h1 > h2 is satisfied. Note that the surface on which the first electrode 107 is arranged is the surface of the first semiconductor substrate 104 on which the second semiconductor substrate 110 is arranged. Note also that the height h1 is the maximum height of the conductive wire 109 from the surface on which the first electrode 107 is arranged. When the angle formed by the normal line of the surface on which the first electrode 107 is arranged and the conductive wire 109 is θ, the conductive wire 109 has a shape inclined to the outside of the first semiconductor substrate 104 at θ = 45° in the vicinity of the height h1. The incident light 111 hitting the region inclined at θ = 45° of the conductive wire 109 reflects on the region not to hit the second semiconductor substrate 110 and advances to the side of the optical member 103. The incident light 111 advanced to the side of the optical member 103 is reflected again on the surface of the optical member 103 facing the first semiconductor substrate 104 and made incident on the first semiconductor substrate 104 inside the second semiconductor substrate 110. That is, in the electronic component illustrated in FIG. 3A and FIG. 3B, since there is a high possibility that the incident light 111 enters the central region 105 of the first semiconductor substrate 104, the wire ghost phenomenon may occur.

Note that, strictly speaking, in the electronic component illustrated in FIG. 3A and FIG. 3B, there is also a possibility that the light advances to the surface of the optical member 103 opposite to the surface of the optical member 103 facing the first semiconductor substrate 104 and is reflected from that surface and re-enters. However, since this re-entering light is weaker than the light reflected on the surface facing the first semiconductor substrate 104, the re-entering light is not illustrated in FIG. 3A and FIG. 3B. The path of the incident light 111 may be changed by a distance d1 between the first electrode 107 and the second semiconductor substrate 110, a width d2 of the second semiconductor substrate 110, and a clearance c1 between the first semiconductor substrate 104 and the optical member 103, and may be a path other than the path described above. In any case, when h1 > h2 is satisfied, there is a high possibility that the incident light 111 reflected on the conductive wire 109 enters the central region 105 of the first semiconductor substrate 104 to generate the wire ghost phenomenon.

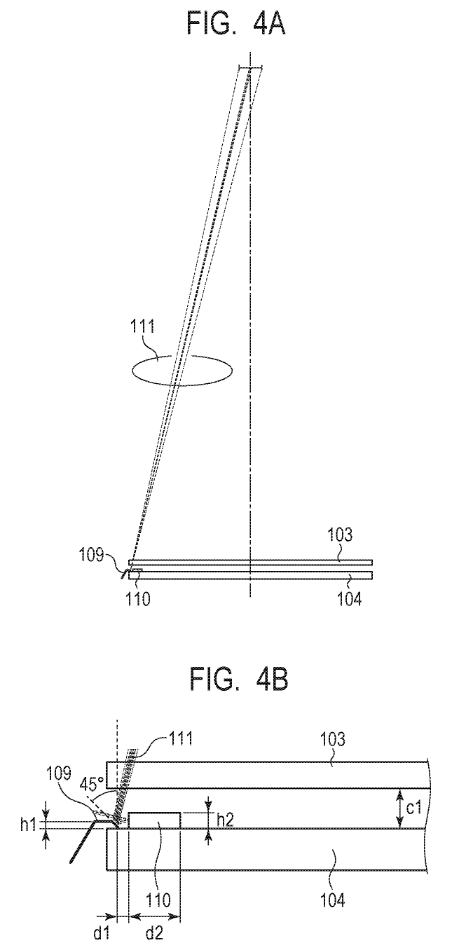

FIG. 4A and FIG. 4B are sectional views illustrating the electronic component 100 according to the present embodiment. FIG. 4A illustrates a state in which the incident light 111 incident from above the optical member 103 hits the conductive wire 109 and is reflected on the conductive wire 109 as in FIG. 3A. FIG. 4B is an enlarged sectional view illustrating the vicinity of the conductive wire 109 in FIG. 4A.

Unlike the electronic components illustrated in FIG. 3A and FIG. 3B, in the electronic component 100 according to the present embodiment, as illustrated in FIG. 4B, h1 < h2 is satisfied. Note that, similarly to FIG. 3A and FIG. 3B, also in FIG. 4A and FIG. 4B, the angle θ formed between the normal line of the surface where the first electrode 107 is arranged and the conductive wire 109 satisfies θ = 45° in the vicinity of height h1. The incident light 111 hitting the region inclined at θ = 45° of the conductive wire 109 is reflected on the region and advances to the side of the second semiconductor substrate 110. The incident light 111 advanced to the side of the second semiconductor substrate 110 is reflected again on the side surface of the second semiconductor substrate 110 facing the conductive wire 109 and advances to the outer edge direction of the first semiconductor substrate 104. That is, in the electronic component 100 according to the present embodiment illustrated in FIG. 4A and FIG. 4B, since the incident light does not enter the central region 105 of the first semiconductor substrate 104, the wire ghost phenomenon does not occur.

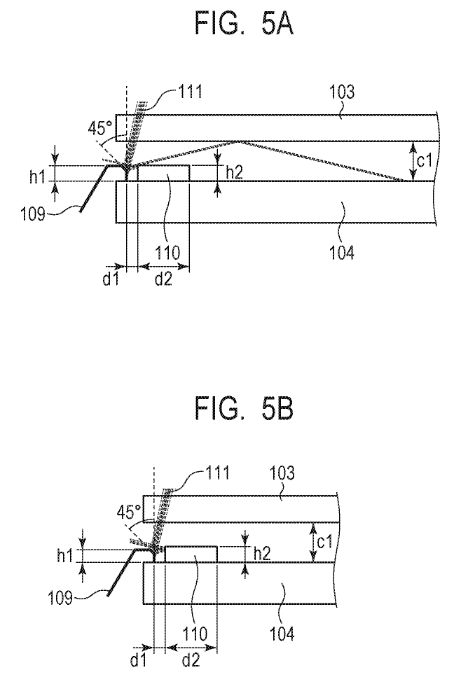

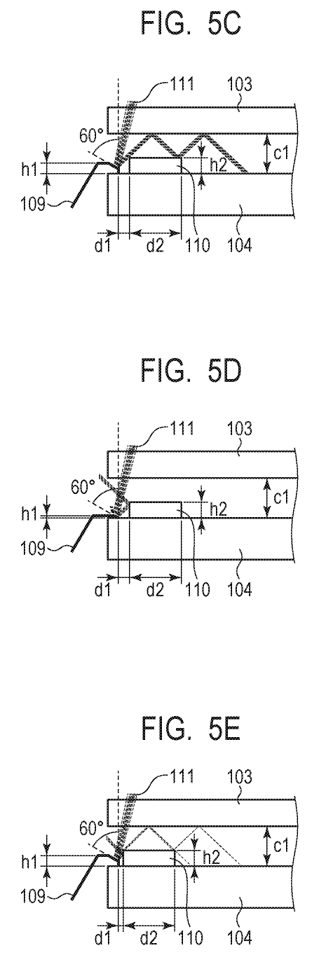

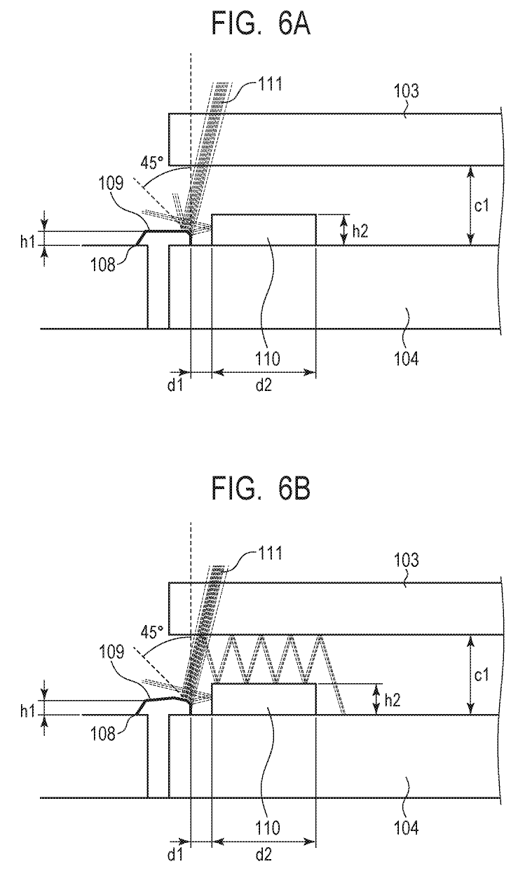

FIG. 5A to FIG. 6B are enlarged sectional views illustrating the vicinity of the electronic component 100 according to the present embodiment and the conductive wire 109 to explain the wire ghost phenomenon, respectively. The cases described in FIG. 3A, FIG. 3B, FIG. 4A, and FIG. 4B will be described in more detail with reference to FIG. 5A to FIG. 6B.

In the cases illustrated in FIG. 5A to FIG. 6B, the clearance c1 between the first semiconductor substrate 104 and the optical member 103 is 0.775 mm, and the width d2 of the second semiconductor substrate 110 is 1.0 mm.

In the case illustrated in FIG. 5A, h1 = h2 = 0.3 mm, θ = 45° near the height h1, and d1 = 0.2 mm. In this case, the incident light 111 incident on the side near the first semiconductor substrate 104 in the region inclined at θ = 45° of the conductive wire 109 is reflected on the side surface of the second semiconductor substrate 110 facing the conductive wire 109, and advances toward the outer edge of the first semiconductor substrate 104. However, in this case, the incident light 111 incident on the side far from the first semiconductor substrate 104 in the region inclined at θ = 45° of the conductive wire 109 exceeds the second semiconductor substrate 110, and is reflected on the surface of the optical member 103 facing the first semiconductor substrate 104. The reflected incident light 111 is incident on the first semiconductor substrate 104. Therefore, in the case illustrated in FIG. 5A, the wire ghost phenomenon may occur.

In the case illustrated in FIG. 5B, h1 = 0.25 mm and other dimensions are the same as those in the case illustrated in FIG. 5A. In this case, all the incident light 111 incident on the inclined region of the conductive wire 109 at θ = 45° is reflected on the side surface of the second semiconductor substrate 110 facing the conductive wire 109 and advances toward the outer edge of the first semiconductor substrate 104. That is, in the case illustrated in FIG. 5B, since the incident light 111 does not enter the central region 105 of the first semiconductor substrate 104, the wire ghost phenomenon does not occur.

In the case illustrated in FIG. 5C, h1 = 0.2 mm, h2 = 0.3 mm, d1 = 0.2 mm, and θ = 60°. In this case, although h1 < h2 is satisfied, the incident light 111 entering the region inclined at θ = 60° of the conductive wire 109 does not hit the second semiconductor substrate 110 but advances to the side of the optical member 103 and is reflected on the surface of the optical member 103 facing the first semiconductor substrate 104. This reflected light is reflected again on the second semiconductor substrate 110. This reflected light reflected again further advances again to the side of the optical member 103, is reflected on the surface of the optical member 103 facing the first semiconductor substrate 104, and is made incident on the first semiconductor substrate 104. Therefore, in the case illustrated in FIG. 5C, the wire ghost phenomenon may occur. However, in the case illustrated in FIG. 5C, since the number of times of reflection is larger than in the case illustrated in FIG. 5A, the quantity of light finally made incident on the first semiconductor substrate 104 is reduced, so that the degree of influence of the wire ghost phenomenon on an image is reduced.

In the case illustrated in FIG. 5D, h1 = 0.04 mm and other dimensions are the same as those of FIG. 5C. In this case, all of the incident light 111 incident on the region inclined at θ = 60° of the conductive wire 109 is reflected on the side surface of the second semiconductor substrate 110 facing the conductive wire 109 and advances in the outer edge direction of the first semiconductor substrate 104. That is, in the case illustrated in FIG. 5D, since the incident light does not enter the central region 105 of the first semiconductor substrate 104, the wire ghost phenomenon does not occur. However, when h1 = 0.04 mm, considering that the diameter of the conductive wire 109 is, for example, about 0.015 mm to 0.03 mm, the clearance between the first semiconductor substrate 104 and the conductive wire 109 is about 0.01 mm to 0.025 mm. Therefore, in the case illustrated in FIG. 5D, there is a possibility that the first semiconductor substrate 104 and the conductive wire 109 come into contact with each other and become defective, including variations in the wire bonding process or the like.

In the case illustrated in FIG. 5E, d1 = 0.1 mm, and other dimensions are the same as those of FIG. 5C. In this case, most of the incident light 111 incident on the region inclined at θ = 60° of the conductive wire 109 is reflected on the side surface of the second semiconductor substrate 110 facing the conductive wire 109 and advances in the outer edge direction of the first semiconductor substrate 104. Most of the incident light 111 is reflected on the side near the first semiconductor substrate 104 in the region inclined at θ=60° of the conductive wire 109. However, a part of the incident light 111 incident on the region inclined at θ = 60° of the conductive wire 109 advances in the following two paths. In the first path, the incident light 111 advances to the side of the optical member 103 without hitting the second semiconductor substrate 110, is reflected on the surface of the optical member 103 facing the first semiconductor substrate 104, and is reflected again on the second semiconductor substrate 110. Further, in the first path, the incident light 111 advances to the side of the optical member 103 again, is reflected on the surface of the optical member 103 facing the first semiconductor substrate 104, and is made incident on the first semiconductor substrate 104. The second path is a path where the incident light 111 advances to the side of the optical member 103 without hitting the second semiconductor substrate 110, is reflected on the surface of the optical member 103 facing the first semiconductor substrate 104, and is made incident on the first semiconductor substrate 104 beyond the second semiconductor substrate 110. In both of the first path and the second path, since the incident light 111 is made incident on the first semiconductor substrate 104, the wire ghost phenomenon may occur. In this case, since the incident light 111 is made incident on two different regions of the first semiconductor substrate 104, the wire ghost phenomenon may occur in two regions. However, in this case, since the amount of light made incident on the first semiconductor substrate 104 is smaller than that illustrated in FIG. 5A and FIG. 5C, the degree of influence of the wire ghost phenomenon on an image is reduced.

In light of the above, in order to further suppress the wire ghost phenomenon, it is preferable that the angle θ formed between the normal line of the surface on which the first electrode 107 is arranged and the conductive wire 109 is smaller than 45° in addition to satisfying h1 < h2. That is, the conductive wire 109 has a region inclined outward with respect to the first semiconductor substrate 104 at the angle θ formed between the conductive wire 109 and the normal line of the surface on which the first electrode 107 is arranged in a region until reaching the height h1, and the angle θ is preferably smaller than 45°. Further, it is preferable that the region inclined at θ of the conductive wire 109 is smaller. Further, it is preferable that the distance d1 between the first electrode 107 and the second semiconductor substrate 110 is smaller. The wider the width d2 of the second semiconductor substrate 110 is, the further the distance from the first electrode 107 to the central region 105 becomes, and in addition the number of times of the reflection increases when there is light reflected on the optical member 103 and the second semiconductor substrate 110. Therefore, the wider the width d2 of the second semiconductor substrate 110 is, the more effectively the wire ghost phenomenon is suppressed. However, since the wide width d2 of the second semiconductor substrate 110 may hinder the miniaturization of the first semiconductor substrate 104, it is preferable to select the width d2 of the second semiconductor substrate 110 in consideration of the overall optimization.

In the cases illustrated in FIG. 6A and FIG. 6B, h1 = 0.15 mm, h2 = 0.3 mm, d1 = 0.2 mm, and θ = 45°, respectively. The configurations of these cases are similar to the configurations of the case illustrated in FIG. 5A and the case illustrated in FIG. 5B, but the difference between these cases and the cases illustrated in FIG. 5A and FIG. 5B is that the second electrode 108 is at the same height as the first electrode 107. In such cases, a region parallel to the surface of the first semiconductor substrate 104 becomes long in the conductive wire 109. Note that the second electrode 108 may be provided on a projecting portion of the substrate 101 and at the same height as the first electrode 107, or may be provided on a semiconductor substrate, which is different from the first semiconductor substrate 104 and provided on the substrate 101, and at the same height as the first electrode 107.

In the case illustrated in FIG. 6A, the conductive wire 109 has an inclined region inclined at θ = 45° near the height h1, and has a parallel region completely parallel to the first semiconductor substrate 104 on the side of the second electrode 108 with respect to the inclined region. Therefore, the incident light 111 incident on the parallel region of the conductive wire 109 is reflected on the parallel region and advances toward the outer edge of the first semiconductor substrate 104.

In the case illustrated in FIG. 6B, the conductive wire 109 has an inclined region inclined at θ = 45° in the vicinity of the height h1, and has a non-parallel region not completely parallel to the first semiconductor substrate 104 but having a slight angle on the side of the second electrode 108 with respect to the inclined region. The incident light 111 incident on the non-parallel region of the conductive wire 109 is reflected on the non-parallel region and advances toward the optical member 103. The incident light 111 that advances toward the optical member 103 is made incident on the first semiconductor substrate 104 after repeating a plurality of times of the reflection on the surface of the optical member 103 facing the first semiconductor substrate 104 and the reflection on the second semiconductor substrate 110. Therefore, in the case illustrated in FIG. 6B, the wire ghost phenomenon may occur. In an actual wire bonding process, it may be assumed that the shape of the conductive wire 109 has the non-parallel region illustrated in FIG. 6B.

Therefore, from the viewpoint of further suppressing the influence of the wire ghost phenomenon, it is preferable that the height of the second electrode 108 is lower than the upper surface of the first semiconductor substrate 104. Further, it is preferable that the region in which the conductive wire 109 and the first semiconductor substrate 104 are parallel is larger.

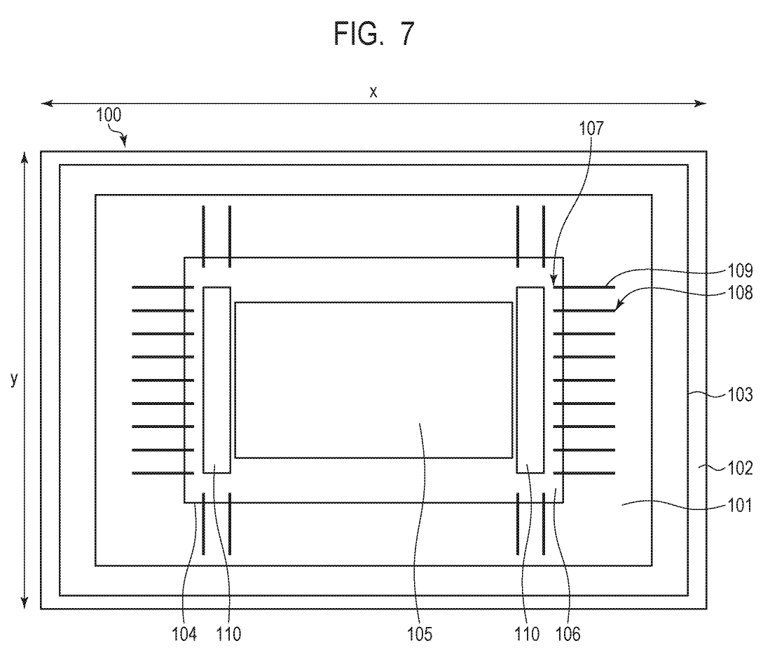

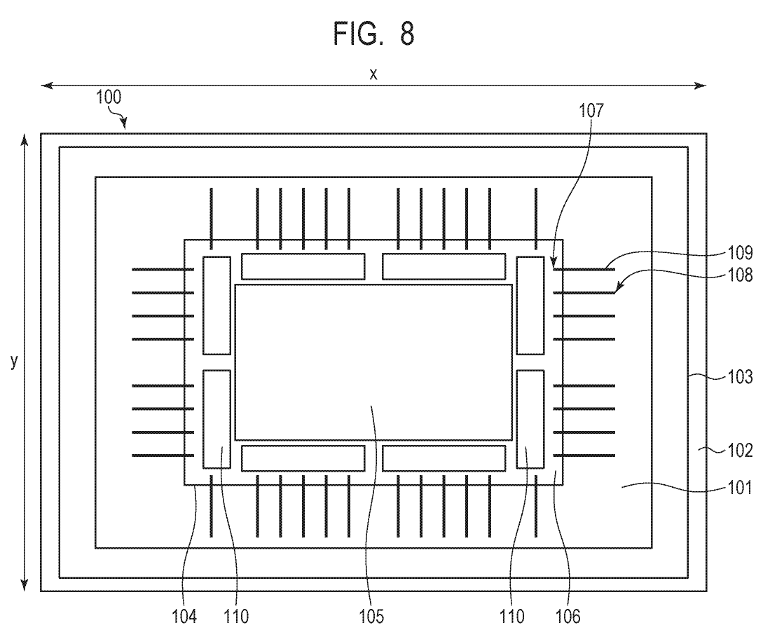

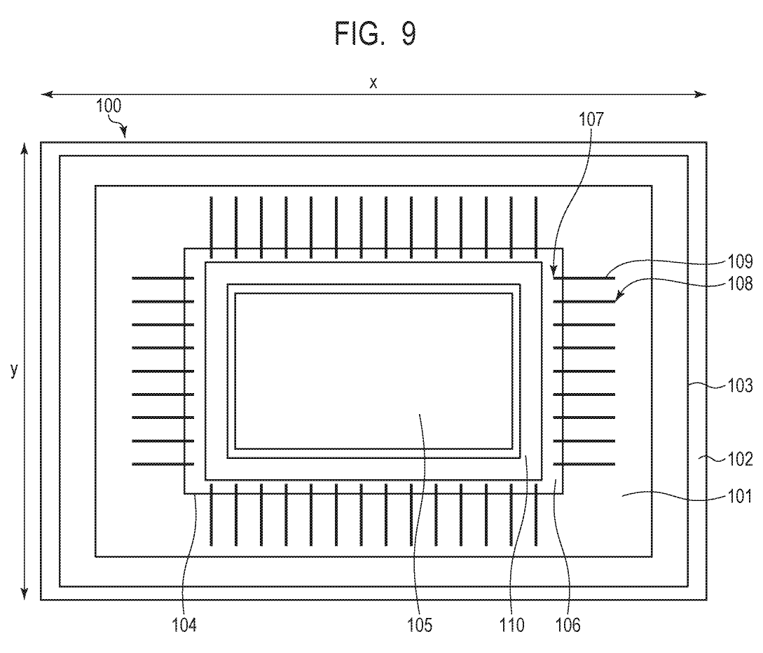

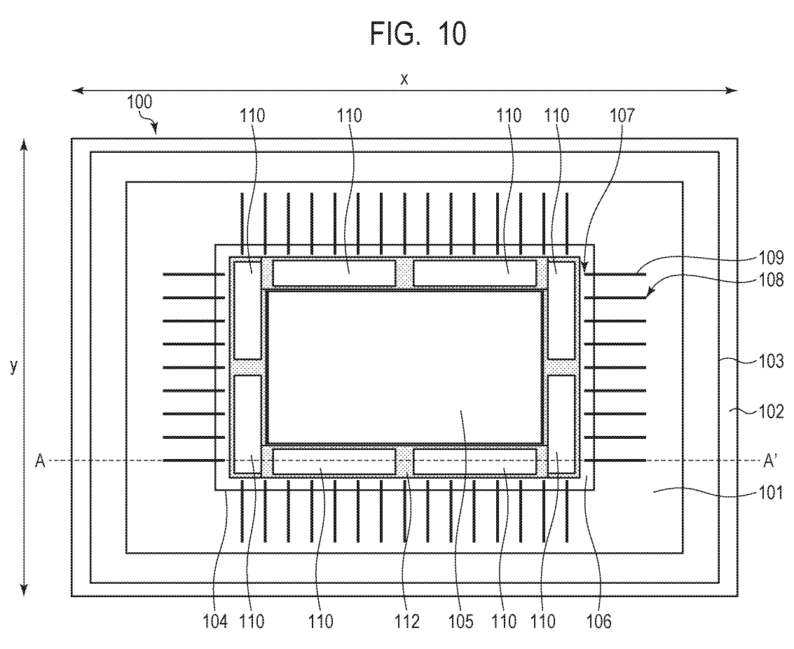

FIG. 7, FIG. 8, and FIG. 9 are plan views illustrating modified examples of the electronic component 100 according to the present embodiment, respectively, which are plan views of the electronic component 100 viewed from the side of the optical member 103. As illustrated in FIG. 7, FIG. 8, and FIG. 9, the arrangement of the second semiconductor substrate 110 and the arrangement of the conductive wires 109 can be appropriately changed.

In the case illustrated in FIG. 7, two second semiconductor substrates 110 are arranged so as to interpose the central region 105 in the two peripheral regions 106 along the sides in the lateral direction of the first semiconductor substrate 104. Further, the conductive wires 109 are not arranged on the sides of the central region 105 along the longitudinal direction of the first semiconductor substrate 104. The arrangement illustrated in FIG. 7 is suitable when the number of conductive wires 109 is small.

In the case illustrated in FIG. 8, a total of the eight second semiconductor substrates 110 are arranged on the peripheral regions 106 along the sides in the lateral direction and the longitudinal direction of the first semiconductor substrate 104, with the two second semiconductor substrates 110 provided on each of the peripheral regions 106. The eight second semiconductor substrates 110 are arranged so as to surround the periphery of the central region 105. On each side, two second semiconductor substrates 110 arranged so as to be adjacent to each other without interposing the central region 105 have clearance. The conductive wires 109 are not arranged in regions facing regions of the clearance. The arrangement illustrated in FIG. 8 is suitable when many functions are arranged in the second semiconductor substrate 110 and when the number of conductive wires 109 is large. Note that the eight second semiconductor substrates 110 are arranged so as to surround the periphery of the central region 105. The number of the second semiconductor substrates 110 arranged on the peripheral region 106 along each side of the first semiconductor substrate 104 is not limited to two, and a plurality of the second semiconductor substrates 110 other than eight in total may be arranged so as to surround the periphery of the central region 105.

As illustrated in FIG. 7 and FIG. 8, the conductive wires 109 may be configured not to be arranged in a region facing the peripheral region 106 where the second semiconductor substrate 110 is not arranged. That is, the conductive wires 109 may not be arranged in a region between the outer edge of the first semiconductor substrate 104 and the central region 105 where the second semiconductor substrate 110 is not arranged.

In the case illustrated in FIG. 9, the second semiconductor substrate 110 having a rectangular annular shape is arranged on the peripheral region 106 so as to completely surround the central region 105. In this case, the conductive wires 109 can be arranged in all regions facing the peripheral regions 106. However, since the second semiconductor substrate 110 having a rectangular annular shape has low versatility, the arrangement illustrated in FIG. 9 may be selected in consideration of overall optimization.

Thus, according to the present embodiment, it is possible to suppress the influence of the wire ghost phenomenon in the electronic component 100.

### Second Embodiment

An electronic component according to a second embodiment of the present disclosure will be described with reference to FIG. 10 to FIG. 12B. Note that the same components as those of the electronic component according to the first embodiment are denoted by the same reference numerals, and description thereof will be omitted or simplified.

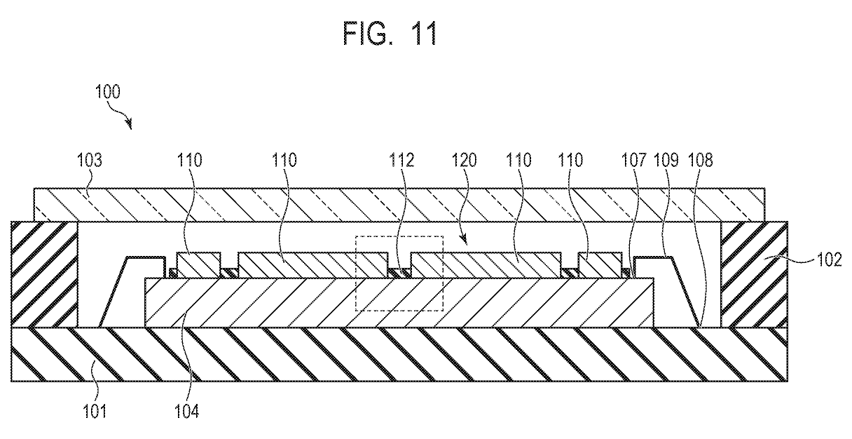

FIG. 10 is a plan view illustrating the electronic component 100 according to the present embodiment, and illustrates a plan view of the electronic component 100 viewed from the side of the optical member 103. FIG. 11 is a cross-sectional view along the line A-A′ in FIG. 10.

As illustrated in FIG. 10, the arrangement of the second semiconductor substrate 110 in the electronic component 100 according to the present embodiment is the same as the arrangement illustrated in FIG. 8 in the first embodiment.

The electronic component 100 according to the present embodiment differs from the electronic component 100 according to the first embodiment in the following first and second points. That is, as illustrated in FIG. 10 and FIG. 11, the first point is that a first bonding member 112 is arranged in clearance regions between the first semiconductor substrate 104 and the second semiconductor substrate 110 and between the second semiconductor substrates 110. The two second semiconductor substrates 110 with the first bonding member 112 arranged in the clearance region are arranged so as to be adjacent to each other without interposing the central region 105. The second point is that the conductive wires 109 are also arranged in regions facing the clearance regions where the first bonding member 112 is arranged. Note that the first bonding member 112 may be arranged in at least any of the clearance regions between the first semiconductor substrate 104 and the second semiconductor substrate 110 and between the second semiconductor substrates 110.

The first bonding member 112 has insulating properties and is, for example, made of resin or the like, specifically, an underfill material or the like. The first bonding member 112 may be colored such as black or the like for suppressing the reflection of light, or may have a shape capable of suppressing reflection of light to the first semiconductor substrate 104 by an uneven or concave-convex shape or the like. Since the first bonding member 112 is arranged in the clearance region between the second semiconductor substrates 110, it is possible to suppress incident light 111 incident on the conductive wires 109 in the region facing the clearance region from being reflected and incident on the central region 105 of the first semiconductor substrate 104. Thus, it is possible to further suppress the influence of the wire ghost phenomenon.

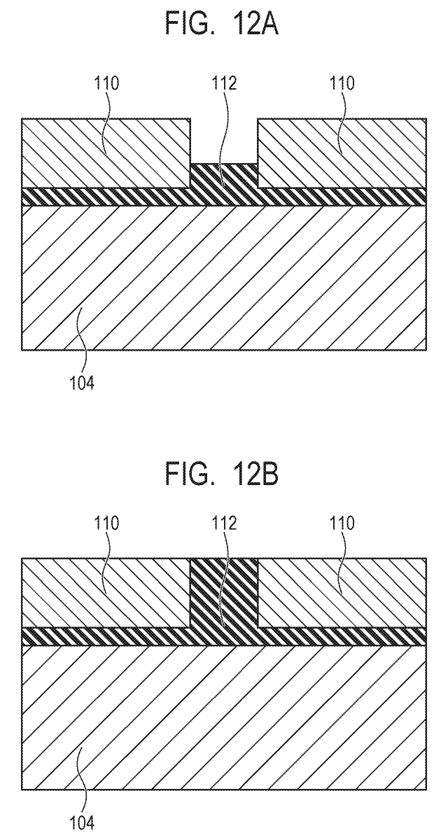

FIG. 12A and FIG. 12B are respectively enlarged sectional views illustrating structures in the broken line frame in FIG. 11. In the case illustrated in FIG. 12A, the first bonding member 112 is arranged to a position lower than the second semiconductor substrate 110. In the case illustrated in FIG. 12B, the first bonding member 112 is arranged up to the same height as the height h2 of the second semiconductor substrate 110. In the present embodiment as well, the influence of the wire ghost phenomenon can be suppressed similarly to the first embodiment by setting the height of the conductive wire 109 to satisfy h1 < h2. Note that the first bonding member 112 may be arranged to the height h2 of the second semiconductor substrate 110 or more.

### Third Embodiment

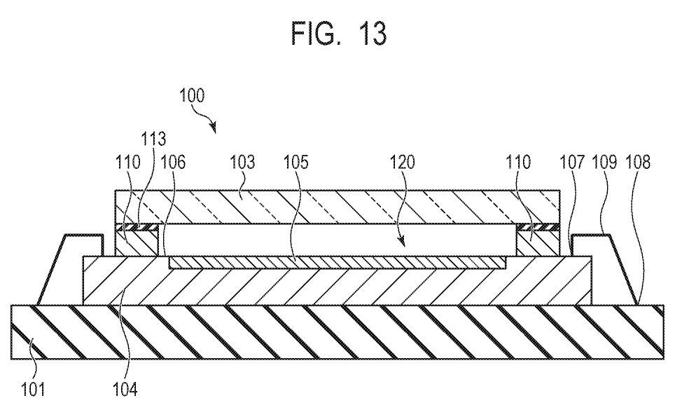

An electronic component according to a third embodiment of the present disclosure will be described with reference to FIG. 13 to FIG. 22. Note that the same components as those of the electronic component according to the first and second embodiments are denoted by the same reference numerals, and description thereof will be omitted or simplified.

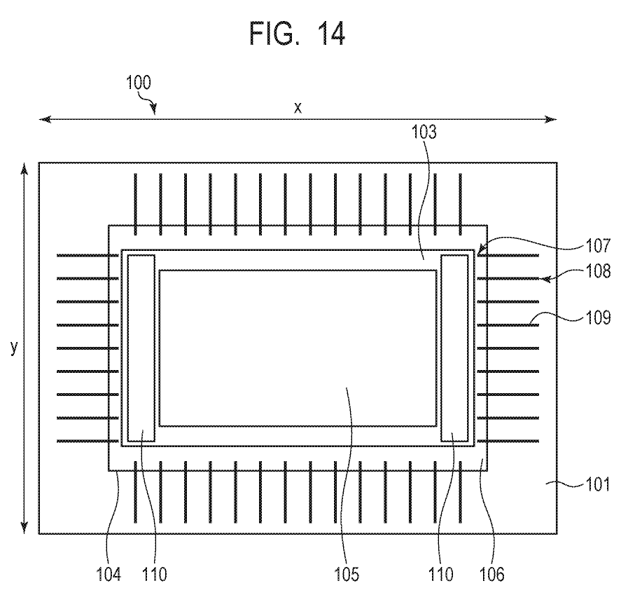

FIG. 13 is a cross-sectional view illustrating the electronic component 100 according to the present embodiment. FIG. 14 is a plan view illustrating the electronic component 100 according to the present embodiment, and illustrates a plan view of the electronic component 100 viewed from the side of the optical member 103.

The electronic component 100 according to the present embodiment is different from the electronic component 100 according to the first and second embodiments in that the frame body 102 is not arranged and the optical member 103 and the second semiconductor substrates 110 are bonded by second bonding members 113. The optical member 103 is bonded to the second semiconductor substrates 110 by the second bonding members 113 so as to cover at least the central region 105 of the first semiconductor substrate 104. Note that the positional relation among the first semiconductor substrate 104, the second semiconductor substrates 110, and the conductive wires 109 in the electronic component 100 according to the present embodiment is the same as the first and second embodiments.

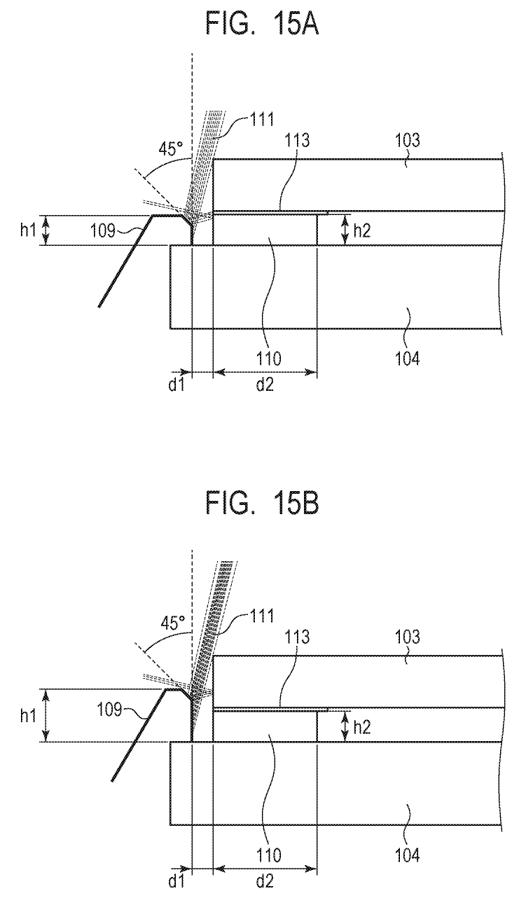

FIG. 15A and FIG. 15B are enlarged sectional views illustrating the vicinity of the conductive wire 109 for explaining the electronic component 100 according to the present embodiment and the wire ghost phenomenon.

In the case illustrated in FIG. 15A, the height h1 of the conductive wire 109 is equal to the height h2 of the second semiconductor substrate 110. Further, θ near the height h1 is 45°. The configuration of the conductive wire 109 and the second semiconductor substrate 110 in the case illustrated in FIG. 15A is the same as the configuration in the case illustrated in FIG. 5A in the first embodiment. In contrast, the configuration in the case illustrated in FIG. 15A is different from the configuration in the case illustrated in FIG. 5A in the first embodiment in that the optical member 103 is bonded to the second semiconductor substrates 110 by the second bonding members 113. In the case illustrated in FIG. 15A, the optical member 103 is bonded to the second semiconductor substrate 110. Therefore, the incident light 111 incident on the conductive wire 109 is reflected to the respective side surfaces of the second semiconductor substrate 110, the second bonding member 113 and the optical member 103, and advances in the outer edge direction of the first semiconductor substrate 104. That is, in the case illustrated in FIG. 15A, since the incident light 111 does not enter the central region 105 of the first semiconductor substrate 104, it is possible to suppress the wire ghost phenomenon.

In the case illustrated in FIG. 15B, h1 > h2 is satisfied. In this case, the incident light 111 entering the conductive wire 109 is reflected on the side surface of the optical member 103 and advances in the outer edge direction of the first semiconductor substrate 104. That is, in the case illustrated in FIG. 15B, since the incident light 111 does not enter the central region 105 of the first semiconductor substrate 104, it is possible to suppress the wire ghost phenomenon.

In the first embodiment, the degree of influence of the wire ghost phenomenon may vary depending on the relationship between the height of the conductive wire 109 and the second semiconductor substrate 110 and the angle of the conductive wire 109. In contrast, in the present embodiment, since it is possible to suppress the wire ghost phenomenon regardless of the height or the angle of the conductive wire 109, it is possible to enhance the degree of freedom regarding the shape of the conductive wire 109.

Note that, for example, an ultraviolet curing adhesive or a thermosetting adhesive may be used as the second bonding member 113. Further, in order to suppress light transmitted through the second bonding member 113, it is preferable to use a colored material such as black for the second bonding member 113 instead of a transparent material having a high light transmittance.

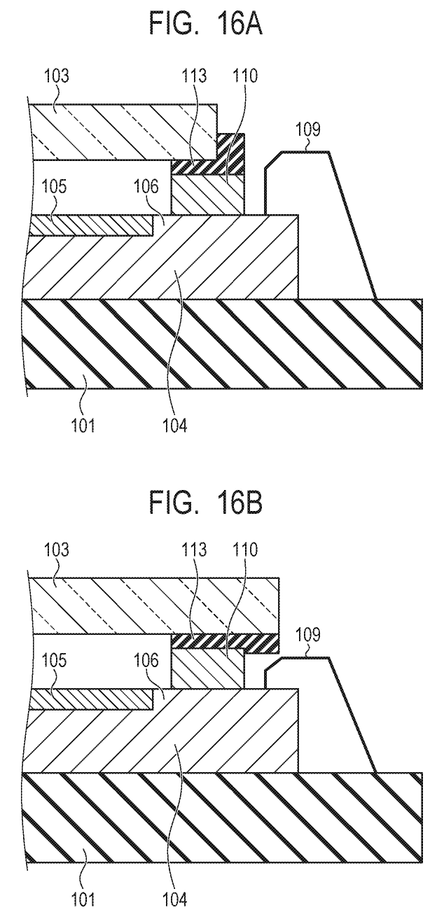

FIG. 16A and FIG. 16B are respectively enlarged sectional views illustrating the vicinity of the conductive wire 109 of the electronic component 100 according to the present embodiment. FIG. 16A and FIG. 16B illustrate examples of structures including the optical member 103, an outer edge of the second bonding member 113, and an outer edge of the second semiconductor substrate 110.

As illustrated in FIG. 16A, the outer edge of the optical member 103 may be positioned inside the outer edge of the second semiconductor substrate 110. Note that the outer edge of the second semiconductor substrate 110 here is the outer edge of the second semiconductor substrate 110 on the opposite side from the central region 105 of the first semiconductor substrate 104. In this case, the second bonding member 113 may be arranged so as to cover at least a part of the outer edge of the optical member 103. At least a part of the outer edge of the optical member 103 covered by the second bonding member 113 includes a part of the side surface of the optical member 103.

Further, as illustrated in FIG. 16B, the outer edge of the optical member 103 may be positioned outside of the outer edge of the second semiconductor substrate 110. Note that the outer edge of the second semiconductor substrate 110 here is also the outer edge of the second semiconductor substrate 110 on the opposite side from the central region 105 of the first semiconductor substrate 104. In this case, the second bonding member 113 may be arranged along the optical member 103 to the outside of the outer edge of the second semiconductor substrate 110. The second bonding member 113 arranged to the outside of the outer edge of the second semiconductor substrate 110 covers a part of the optical member 103 on the rear surface of the optical member 103 on the side of the first semiconductor substrate 104, which is outside of the outer edge of the second semiconductor substrate 110.

The components of light entering from the side or the rear surface of the optical member 103 and reaching the central region 105 are inherently small. However, as illustrated in FIG. 16A and FIG. 16B, since the second bonding member 113 covers the side or the rear surface of the optical member 103, it is possible to further enhance the suppression effect of the wire ghost phenomenon.

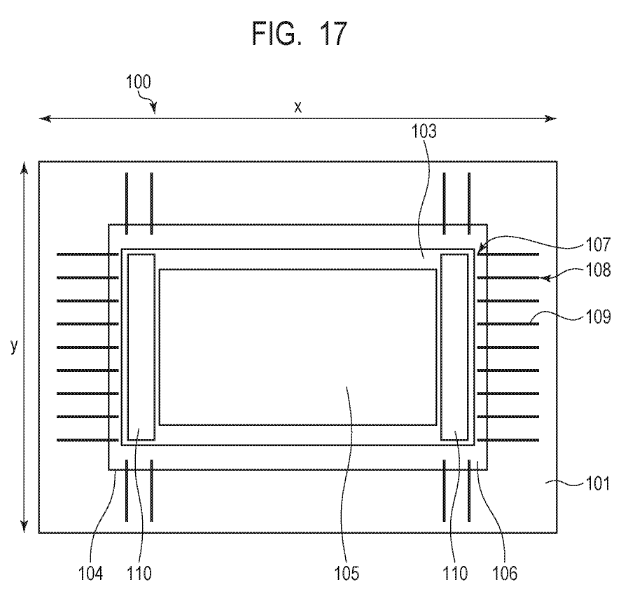

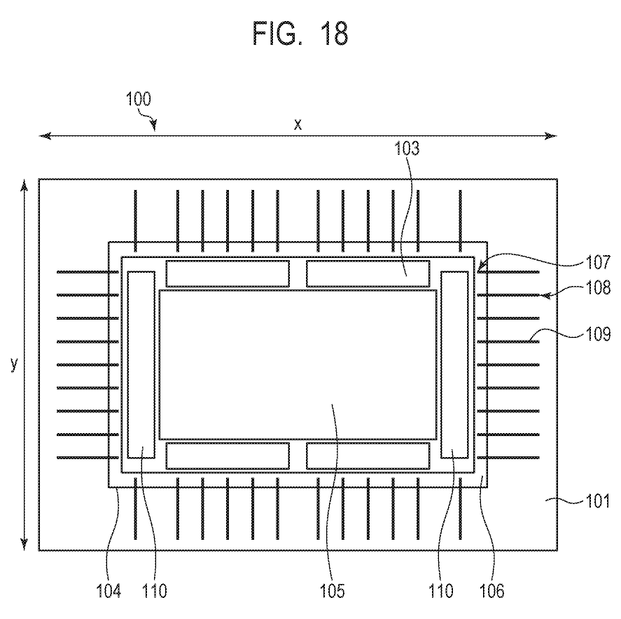

FIG. 17 and FIG. 18 are plan views respectively illustrating modified examples of the electronic component 100 according to the present embodiment, which are plan views of the electronic component 100 viewed from the side of the optical member 103. FIG. 17 and FIG. 18 illustrate cases where the conductive wire 109 is arranged in the same manner as illustrated in FIG. 7 and FIG. 8 of the first embodiment, respectively. Also in the present embodiment, the conductive wires 109 may be arranged not in the region facing the peripheral region 106 where the second semiconductor substrate 110 is not arranged as illustrated in FIG. 7 and FIG. 8 of the first embodiment. Such an arrangement of the conductive wires 109 makes it possible to suppress the influence of the wire ghost phenomenon.

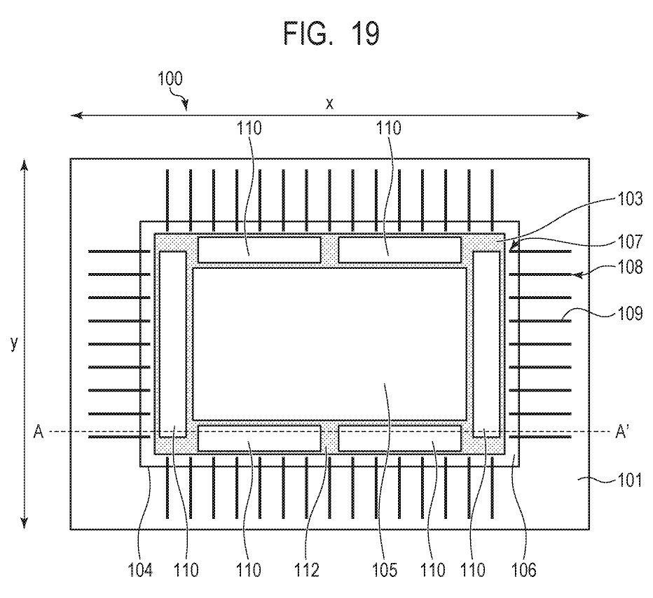

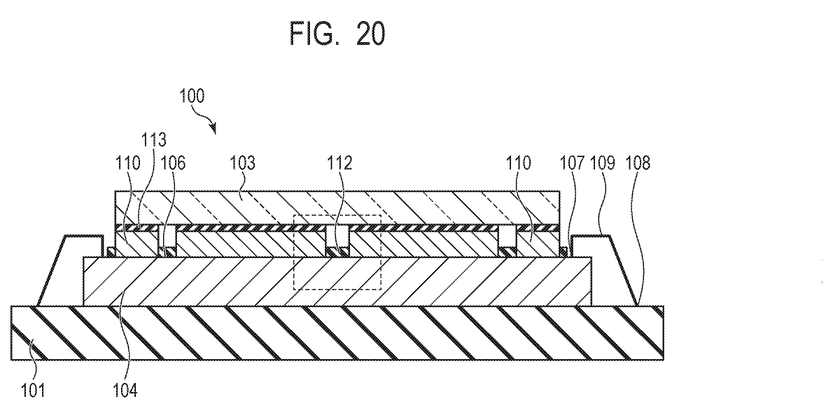

Also in the present embodiment, the first bonding member 112 may be arranged as in the second embodiment. FIG. 19 is a plan view of the electronic component 100 according to the present embodiment in which the first bonding member 112 is arranged, which is a plan view of the electronic component 100 viewed from the side of the optical member 103. FIG. 20 is a cross-sectional view along the line A-A′ in FIG. 19.

As illustrated in FIG. 19 and FIG. 20, also in the present embodiment, the first bonding member 112 may be arranged in the clearance region between the first semiconductor substrate 104 and the second semiconductor substrate 110 and between the second semiconductor substrates 110 as in FIG. 10 and FIG. 11 of the second embodiment. Also in the present embodiment, with the first bonding member 112 arranged, it is possible to suppress the incident light 111 incident on the conductive wire 109 in the region facing the clearance region from being reflected and incident on the central region 105 of the first semiconductor substrate 104. In order to suppress the reflection of light, the first bonding member 112 and the second bonding member 113 may be colored black or the like, or may be shaped to suppress reflection of light on the first semiconductor substrate 104 by having an uneven or concave-convex shape or the like.

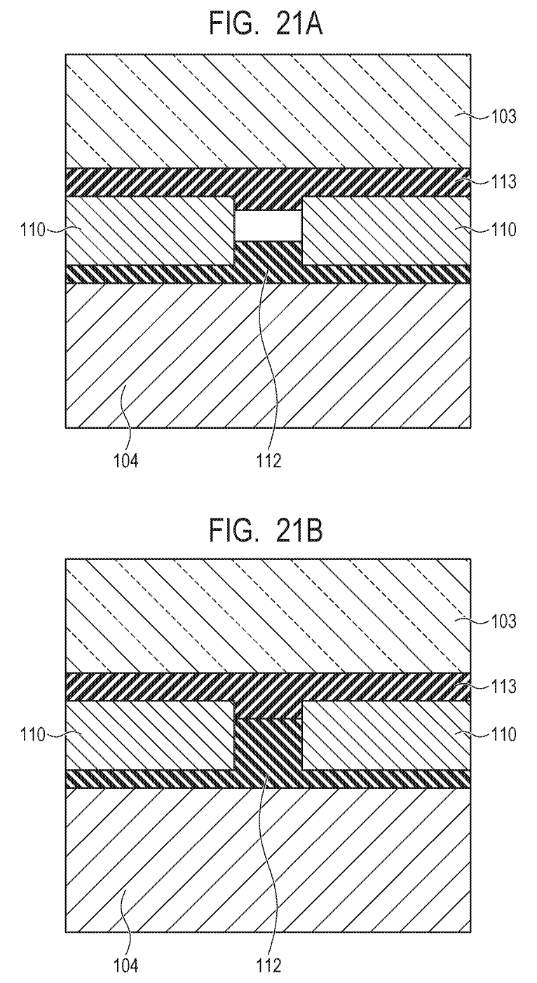

FIG. 21A and FIG. 21B are respectively enlarged sectional views illustrating the structure in the broken line frame in FIG. 20. As illustrated in FIG. 21A and FIG. 21B, the two second semiconductor substrates 110 are arranged so as to be adjacent to each other without interposing the central region 105 of the first semiconductor substrate 104. In the clearance region between these two second semiconductor substrates 110, a space between the first semiconductor substrate 104 and the optical member 103 is covered by both of the first bonding member 112 and the second bonding member 113. Note that, in this case, the space between the first semiconductor substrate 104 and the optical member 103 may be covered by either of the first bonding member 112 and the second bonding member 113.

In the case illustrated in FIG. 21A, there is a clearance between the first bonding member 112 and the second bonding member 113 in the clearance region between the second semiconductor substrates 110. In the case illustrated in FIG. 21B, the first bonding member 112 and the second bonding member 113 are arranged so as to contact each other so that there is no clearance between the first bonding member 112 and the second bonding member 113 in the clearance region between the second semiconductor substrates 110. In this case, even in the region where the second semiconductor substrate 110 is not arranged, since the light reflected from the conductive wire 109 does not directly enter the first semiconductor substrate 104 due to the first bonding member 112 and the second bonding member 113, it is possible to further suppress the influence of the wire ghost phenomenon.

In addition, in the configuration illustrated in FIG. 13 to FIG. 21B, since there is no frame body 102 and there is no clearance between the optical member 103 and the second semiconductor substrate 110, it is possible to obtain an effect of miniaturizing the electronic component 100.

Note that, in order to protect the central region 105, which is being a detection region of the first semiconductor substrate 104, and the conductive wires 109 from an external environment, the peripheral regions 106 of the first semiconductor substrate 104 and the conductive wires 109 may be covered with a sealing material or the like not illustrated as necessary. Protection from an external environment includes suppression of intrusion of foreign substances or moisture.

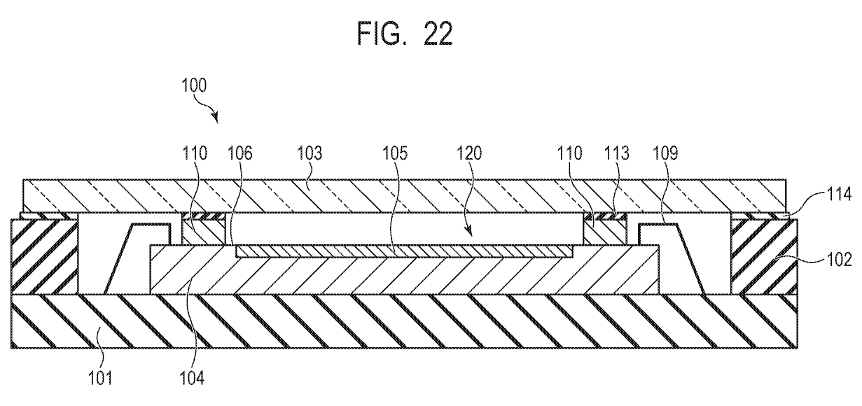

The electronic component 100 according to the present embodiment may also be provided with the frame body 102. FIG. 22 is a sectional view illustrating a configuration in which the frame body 102 is further arranged in the electronic component 100 according to the present embodiment. The configuration illustrated in FIG. 22 is different from the configuration illustrated in FIG. 13 in that the frame body 102 is arranged, the second semiconductor substrate 110 and the optical member 103 are bonded by the second bonding member 113, and in addition the frame body 102 and the optical member 103 are bonded by the third bonding member 114.

As illustrated in FIG. 22, the frame body 102 is adhered to one surface of the substrate 101 so as to surround a region of the substrate 101 where the first semiconductor substrate 104 and the conductive wires 109 are arranged. The optical member 103 is bonded to the upper surfaces of the second semiconductor substrates 110 by the second bonding members 113. Further, the optical member 103 is bonded to the frame surface of the frame body 102 on the opposite side to the substrate 101 by the third bonding member 114.

In the configuration illustrated in FIG. 22, the effect of suppressing the influence of the wire ghost phenomenon is equivalent to the configurations illustrated in FIG. 13 to FIG. 21B, but the central region 105 of the first semiconductor substrate 104 and the conductive wires 109 can be easily protected from the external environment by the frame body 102.

Note that the second bonding member 113 between the second semiconductor substrate 110 and the optical member 103 and the third bonding member 114 between the frame body 102 and the optical member 103 may be the same member or different members.

Further, in the configuration illustrated in FIG. 22, since the optical member 103 is bonded on the plurality of second semiconductor substrates 110 and the frame body 102, the influence of the variation in height of each component member may occur. Therefore, in the configuration illustrated in FIG. 22, in order to precisely bond the optical member 103 without inclination, the thickness, material, and the like of the second bonding member 113 may be changed for each component member to absorb the variations in height.

### Fourth Embodiment

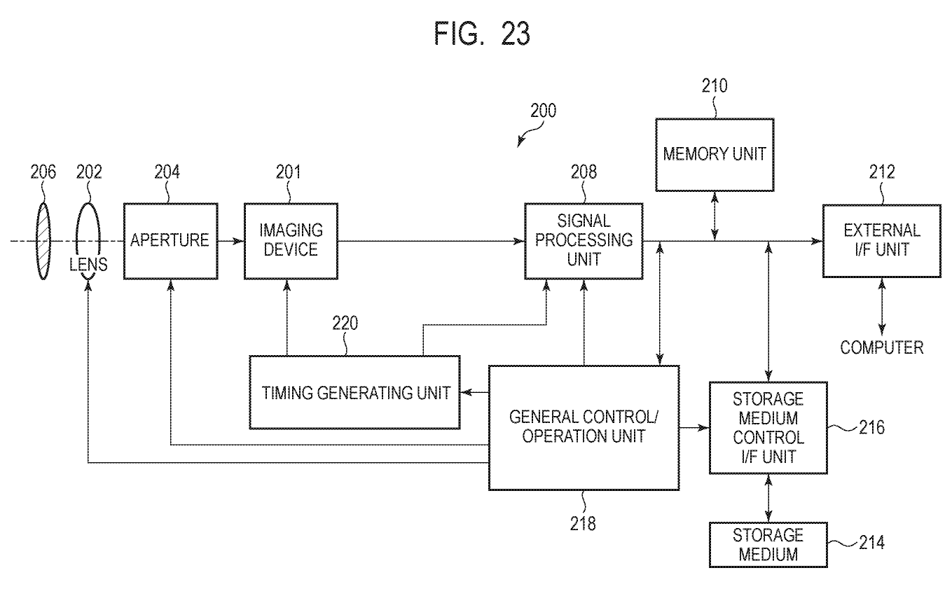

A photoelectric conversion system according to a fourth embodiment of the present disclosure will be described with reference to FIG. 23. FIG. 23 is a block diagram illustrating a schematic configuration of a photoelectric conversion system according to the present embodiment.

The electronic component 100 described in the first to third embodiments is applicable to various photoelectric conversion systems. Examples of applicable photoelectric conversion systems include a digital still camera, a digital camcorder, a surveillance camera, a copier, a fax, a cellular phone, an in-vehicle camera, an observation satellite, and the like. A camera module including an optical system such as a lens and an imaging device is also included in the photoelectric conversion system. FIG. 23 illustrates a block diagram of a digital still camera as an example of them.

The photoelectric conversion system 200 illustrated in FIG. 23 includes an imaging device 201, a lens 202 that forms an optical image of an object on the imaging device 201, an aperture 204 that varies the amount of light passing through the lens 202, and a barrier 206 that protects the lens 202. The lens 202 and the diaphragm 204 are optical systems for focusing light on the imaging device 201. The imaging device 201 is the electronic component 100 described in any of the first to third embodiments, and converts an optical image formed by the lens 202 into image data.

The photoelectric conversion system 200 also includes a signal processing unit 208 that processes an output signal output from the imaging device 201. The signal processing unit 208 generates image data from the digital signal output from the imaging device 201. The signal processing unit 208 performs various types of correction and compression as necessary to output image data. The imaging device 201 may include an AD conversion unit that generates a digital signal to be processed by the signal processing unit 208. The AD conversion unit may be formed on a semiconductor layer (semiconductor substrate) on which the photoelectric converter of the imaging device 201 is formed, or may be formed on a semiconductor layer different from the semiconductor layer on which the photoelectric converter of the imaging device 201 is formed. The signal processing unit 208 may be formed on the same semiconductor layer as the imaging device 201.

The photoelectric conversion system 200 further includes a memory unit 210 that temporarily stores image data, and an external interface unit (external I/F unit) 212 that communicates with an external computer or the like. The photoelectric conversion system 200 further includes a storage medium 214 such as a semiconductor memory that records or reads out image data, and a storage medium control interface unit (storage medium control I/F unit) 216 that records or reads out image data on or from the storage medium 214. The storage medium 214 may be built in in the photoelectric conversion system 200 or may be detachable.

The photoelectric conversion system 200 further includes a general control/operation unit 218 that performs various calculations and controls the entire digital still camera, and a timing generating unit 220 that outputs various timing signals to the imaging device 201 and the signal processing unit 208. Here, timing signal or the like may be input from outside, and the photoelectric conversion system 200 may include at least the imaging device 201 and the signal processing unit 208 that processes the output signal output from the imaging device 201.

The imaging device 201 outputs an imaging signal to the signal processing unit 208. The signal processing unit 208 performs predetermined signal processing on an imaging signal output from the imaging device 201, and outputs image data. The signal processing unit 208 generates an image by using the imaging signal.

As described above, according to the present embodiment, a photoelectric conversion system to which the electronic component 100 according to the first to third embodiments is applied may be realized.

### Fifth Embodiment

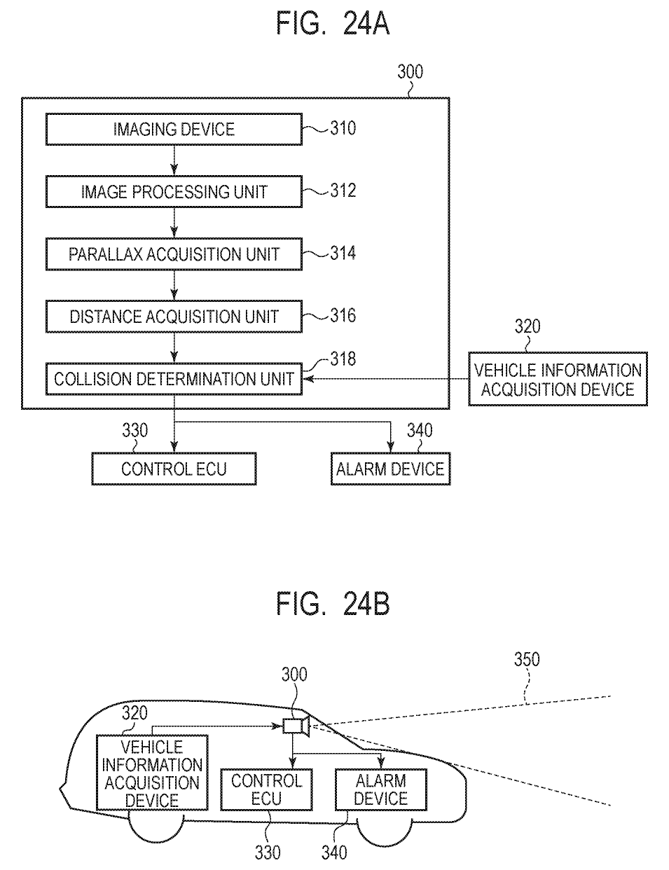

A photoelectric conversion system and a movable object according to a fifth embodiment of the present disclosure will be described with reference to FIG. 24A and FIG. 24B. FIG. 24A and FIG. 24B are diagrams illustrating configurations of a photoelectric conversion system and a movable object according to the present embodiment.

FIG. 24A illustrates an example of a photoelectric conversion system related to an in-vehicle camera. The photoelectric conversion system 300 includes an imaging device 310. The imaging device 310 is the electronic component 100 according to any one of the first to third embodiments. The photoelectric conversion system 300 includes an image processing unit 312 that performs image processing on a plurality of image data acquired by the imaging device 310, and a parallax acquisition unit 314 that calculates parallax (phase difference of parallax images) from the plurality of image data acquired by the imaging device 310. The photoelectric conversion system 300 also includes a distance acquisition unit 316 that calculates the distance to an object based on the calculated parallax, and a collision determination unit 318 that determines whether there is a possibility of collision based on the calculated distance. Here, the parallax acquisition unit 314 and the distance acquisition unit 316 are an example of a distance information acquisition unit that acquires distance information to the object. That is, the distance information is information relating to parallax, a defocus amount, distance to an object, and the like. The collision determination unit 318 may determine the possibility of collision using any of the distance information. The distance information acquisition means may be realized by hardware designed exclusively, or may be realized by a software module. It may be realized by FPGA (Field Programmable Gate Array), ASIC (Application Specific Integrated Circuit), or the like, or may be realized by a combination of these.

The photoelectric conversion system 300 is connected to a vehicle information acquisition device 320, and may acquire vehicle information such as a vehicle speed, a yaw rate, and a steering angle. Further, the photoelectric conversion system 300 is connected to a control ECU 330, which is a control device that outputs a control signal for generating a braking force to the vehicle based on the determination result obtained by the collision determination unit 318. The photoelectric conversion system 300 is also connected to an alarm device 340 that issues an alarm to the driver based on the determination result obtained by the collision determination unit 318. For example, when the possibility of collision is high as the determination result of the collision determination unit 318, the control ECU 330 performs vehicle control to avoid collision and reducing damage by applying a brake, returning an accelerator, suppressing an engine output, or the like. The alarm device 340 sounds an alarm such as a sound, displays alarm information on a screen of a car navigation system or the like, and provides a warning to the user by applying vibration to a seatbelt or steering.

In the present embodiment, an image of the periphery of the vehicle, for example, the front or the rear is captured by the photoelectric conversion system 300. FIG. 24B illustrates a photoelectric conversion system in the case of capturing an image of the front of a vehicle (imaging range 350). The vehicle information acquisition device 320 sends an instruction to the photoelectric conversion system 300 or the imaging device 310. With such a configuration, the accuracy of distance measurement may be further improved.

Although an example in which the vehicle is controlled so as not to collide with another vehicle has been described above, the disclosure is also applicable to a control in which the vehicle is automatically driven following another vehicle, a control in which the vehicle is automatically driven so as not to protrude from a lane, and the like. Further, the photoelectric conversion system may be applied not only to a vehicle such as a host vehicle, but also to a movable object (mobile device) such as a ship, an aircraft, or an industrial robot. In addition, the disclosure may be applied not only to a movable object but also to an apparatus using object recognition in a wide range such as an advanced road traffic system (ITS).

### Modification Embodiments

The present disclosure is not limited to the embodiments described above, and various modifications are possible. For example, cases where some configurations of any of the embodiments are added to another embodiment, or cases where some configurations of any of the embodiments are replaced with some configurations of another embodiment, are also embodiments of the present disclosure.

In the present specification, expressions such as “A or B”, “at least one of A and B”, “at least one of A and/or B”, “one or more of A and/or B”, and the like can include all possible combinations of the listed items unless otherwise expressly defined. That is, the above expressions are to be understood as disclosing all cases: the case including at least one A, the case including at least one B, and the case including both at least one A and at least one B. This similarly applies to combinations of three or more elements.

The embodiments described above may be modified as appropriate without departing from the technical idea. Note that the disclosure content of the present specification includes not only what is stated in the present specification but also all matters that can be understood from the present specification and the drawings attached to the present specification. Furthermore, the disclosure content of the present specification includes the complement of the concepts described in the present specification. That is, if the present specification states, for example, that “A is greater than B” even if the statement “A is not greater than B” is omitted, the present specification can be said to disclose that “A is not greater than B”. This is because when the present specification states that “A is greater than B”, it is presupposed that the case “A is not greater than B” has been considered.

According to the present disclosure, it is possible to suppress the influence of the wire ghost phenomenon in an electronic component.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-228895, filed December 25, 2024, which is hereby incorporated by reference herein in its entirety.

What is claimed is:

1. An electronic component comprising:
a substrate;
a first semiconductor substrate arranged on the substrate, the first semiconductor substrate having a first region that detects light and a second region outside the first region;
a second semiconductor substrate arranged on the first semiconductor substrate and bonded to the first semiconductor substrate;
an optical member facing the first semiconductor substrate and the second semiconductor substrate with a hollow portion between the optical member and the first and second substrates, the optical member being transparent to the light;
a plurality of first electrodes arranged in the second region;
a plurality of second electrodes arranged in a region of the substrate that is outside a region where the first semiconductor substrate is arranged; and
a conductive wire connecting the first electrode and the second electrode,
wherein the second semiconductor substrate is arranged between the first region and the first electrode,
wherein, when a maximum height of the conductive wire from a surface of the first semiconductor substrate on which the first electrode is arranged is defined as h1, and a height of the second semiconductor substrate is defined as h2, h1 < h2 is satisfied,
wherein the conductive wire has a region that is inclined outward with respect to the first semiconductor substrate at an angle θ, the angle θ being formed between the conductive wire and a normal line of the surface on which the first electrode is arranged, in a region of the conductive wire up to the height h1, and
wherein the angle θ is less than 45°.

2. An electronic component comprising:
a substrate;
a first semiconductor substrate arranged on the substrate, the first semiconductor substrate having a first region that detects light and a second region outside the first region;
a second semiconductor substrate arranged on the first semiconductor substrate and bonded to the first semiconductor substrate;
an optical member that is transparent to the light;
a plurality of first electrodes arranged in the second region;
a plurality of second electrodes arranged in a region of the substrate that is outside a region where the first semiconductor substrate is arranged; and
a conductive wire connecting the first electrode and the second electrode,
wherein the second semiconductor substrate is arranged between the first region and the first electrode, and
wherein the optical member is bonded to the second semiconductor substrate by a second bonding member so as to cover at least the first region.

3. The electronic component according to claim 1, wherein the two or more second semiconductor substrates are arranged.

4. The electronic component according to claim 1, wherein the conductive wire is not arranged in a region between an outer edge of the first semiconductor substrate and the first region, where the second semiconductor substrate is not arranged.

5. The electronic component according to claim 1, wherein a first bonding member is arranged between the first semiconductor substrate and the second semiconductor substrate, the first bonding member having insulating properties.

6. The electronic component according to claim 5,
wherein the second semiconductor substrate includes the two second semiconductor substrates arranged adjacent to each other without the first region therebetween, and
wherein the first bonding member is arranged between the two second semiconductor substrates.

7. The electronic component according to claim 6, wherein the first bonding member is arranged at a height that is equal to or greater than a height of the second semiconductor substrate.

8. The electronic component according to claim 5, wherein the first bonding member is colored.

9. The electronic component according to claim 1, wherein the second semiconductor substrate is arranged so as to surround a periphery of the first region.

10. The electronic component according to claim 2, wherein the optical member is bonded to the second semiconductor substrate by the second bonding member.

11. The electronic component according to claim 10, wherein an outer edge of the optical member is positioned inside an outer edge of the second semiconductor substrate on a side opposite to a central region of the first semiconductor substrate.

12. The electronic component according to claim 11, wherein the second bonding member is arranged so as to cover at least a part of the outer edge of the optical member.

13. The electronic component according to claim 10, wherein an outer edge of the optical member is positioned outside of an outer edge of the second semiconductor substrate on a side opposite to a central region of the first semiconductor substrate.

14. The electronic component according to claim 13, wherein the second bonding member is arranged on at least a part of the surface facing the first semiconductor substrate, in a region of the optical member that is outside the outer edge of the second semiconductor substrate.

15. The electronic component according to claim 10,
wherein the second semiconductor substrate includes the two second semiconductor substrates arranged adjacent to each other without the first region therebetween,
wherein a first bonding member is arranged between the two second semiconductor substrates, the first bonding member having insulating properties, and
wherein in a region between the two second semiconductor substrates, a space between the first semiconductor substrate and the optical member is covered by at least one of the first bonding member and the second bonding member.

16. The electronic component according to claim 15, wherein a clearance exists between the first bonding member and the second bonding member in a region between the two second semiconductor substrates.

17. The electronic component according to claim 15, wherein the first bonding member and the second bonding member are in contact with each other in a region between the two second semiconductor substrates.

18. The electronic component according to claim 10, further comprising a frame body surrounding a region where the first semiconductor substrate and the conductive wire are arranged,
wherein the optical member is bonded to the frame body by a third bonding member.

19. A photoelectric conversion system comprising:
the electronic component according to claim 1; and
a signal processing device that processes a signal output from the electronic component.

20. A movable object comprising:
the electronic component according to claim 1;
a distance information acquisition unit that acquires distance information to an object from a parallax image based on a signal output from the electronic component; and
a control unit that controls the movable object based on the distance information.
